(19) United States
(12) Patent Application Publication
(10) Pub. No.: US 2005/0011447 A1
(43) Pub. Date: Jan. 20, 2005

(54) Method and apparatus for delivering process gas to a process chamber

(75) Inventor: Steven T. Fink, Mesa, AR (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/889,220

(22) Filed: Jul. 13, 2004

Related U.S. Application Data
(60) Provisional application No. 60/486,458, filed on Jul. 14, 2003.
(60) Provisional application No. 60/503,890, filed on Sep. 22, 2003.

(51) Int. Cl. C23C 16/00

(52) U.S. Cl. 118/715

(57) ABSTRACT

A gas delivery system for a plasma apparatus including a first plate having a gas inlet, and a second plate having a plurality of holes. The second plate is coupled to the first plate and spaced apart from the second to form a plenum chamber. A baffle honeycomb core is disposed between the first plate and the second plate in side the plenum chamber. The honeycomb core can be comprised of one or more spaced apart honeycomb panels. A surface of one of the honeycomb panels or a surface of the first panel can be contoured to control the pressure distribution of a gas in the plenum chamber. The gas delivery assembly for a plasma apparatus also includes a first plate having a gas inlet and a second plate coupled to the first plate to form a plenum chamber therebetween. The second plate includes a gas injection plate having a plurality of holes. The gas injection plate has a contoured surface such that a length of each of the plurality of holes varies depending on location of the holes on the contoured surface.

### CROSS-REFERENCE TO RELATED APPLICATIONS

This non-provisional application relies upon, and claims the benefit of the filing dates, of U.S. Provisional Application Nos. 60/486,458, filed on Jul. 14, 2003, and 60/503,890, filed on Sep. 22, 2003, the contents of both of which are incorporated herein by reference in their entireties.

### FIELD OF THE INVENTION

The present invention pertains to plasma processing systems and in particular to an apparatus for delivering a process gas to a process chamber.

### BACKGROUND OF THE INVENTION

Plasma processing systems are used in the manufacture and processing of semiconductors, integrated circuits, displays and other devices and materials, to remove material from, deposit material on or chemically or mechanically alter a substrate such as a semiconductor substrate. In some instances, these plasma processing systems use energy to create a plasma useful for depositing on or removing material from a substrate.

There are several different kinds of plasma processes used during wafer or substrate processing. These processes include, for example: plasma etching, plasma deposition, plasma assisted photoresist stripping and in-situ plasma chamber cleaning.

Plasma processing systems often operate with a blend of gasses which must flow through a processing chamber. The gasses are introduced into the processing system through a plurality of holes in an injection plate or a shower head. A pumping system is employed to remove gasses from the processing system.

### BRIEF SUMMARY OF THE INVENTION

An aspect of the present invention is to provide a gas delivery assembly for a plasma apparatus, including a first plate having a gas inlet, a second plate having a plurality of holes, the second plate being coupled to the first plate and spaced apart from the first plate to form a plenum chamber, and a baffle honeycomb core assembly disposed between the first plate and the second plate inside the plenum chamber. In one embodiment, the honeycomb core can be comprised of, for example, one or more spaced apart honeycomb panels. In another embodiment, a surface of one of the honeycomb panels or a surface of the first plate can be contoured to control the pressure distribution of a gas in the plenum chamber.

Another aspect of the present invention is to provide a plasma reactor including a vacuum chamber, a chuck assembly, a plasma source assembly; and a gas delivery assembly. The gas delivery assembly includes a first plate having a gas inlet, a second plate having a plurality of holes. The second plate is coupled to the first plate and spaced apart from the first plate to form a plenum chamber. The gas delivery assembly further includes a baffle honeycomb core disposed between the first plate and the second plate inside the plenum chamber.

Another aspect of the present invention is to provide a gas delivery assembly for a plasma apparatus including a first plate having a gas inlet and a second plate coupled to the first plate and spaced apart from the first plate to form a plenum chamber. The second plate includes a gas injection plate having a plurality of holes. The gas injection plate has a contoured surface such that a length of each of the plurality of holes varies depending on location of the holes on the contoured surface. In one embodiment, the contoured surface is such that the injection plate is thicker in a central portion thereof and thinner in a peripheral portion thereof. In another embodiment, the contoured surface is such that the injection plate is thinner in a central portion thereof and thicker in a lateral portion thereof The distribution of gas pressure after passage through the injection plate can be made substantially uniform. The gas delivery assembly may further include a gas baffle assembly to further control the distribution of gas pressure.

Another aspect of the present invention is to provide a plasma reactor including a vacuum chamber, a chuck assembly, a plasma source assembly; and a gas delivery assembly. The gas delivery assembly includes a first plate having a gas inlet and a second plate coupled to the first plate and spaced apart from the first plate to form a plenum chamber. The second plate includes a gas injection plate having a plurality of holes. The gas injection plate has a contoured surface such that a length of each of the plurality of holes varies depending on location of the holes on the contoured surface.

### BRIEF DESCRIPTION OF THE DRAWINGS

In the accompanying drawings:

FIG. 1 is a cross-sectional view of a plasma reactor comprising a gas delivery assembly, according to an embodiment of the present invention;

FIG. 2 is a cross-sectional view of a plasma reactor comprising a gas delivery assembly, according to another embodiment of the present invention;

FIG. 3 is a cross-sectional view of a plasma reactor comprising a gas delivery assembly, according to another embodiment of the present invention;

FIG. 4 is a cross-sectional view of a gas delivery assembly according to one embodiment of the present invention;

FIG. 5 is a cross-sectional view of a gas delivery assembly according to another embodiment of the present invention;

FIG. 6 is a cross-sectional view of a gas delivery assembly according to another embodiment of the present invention;

FIG. 7 is a cross-sectional view of a gas delivery assembly according to another embodiment of the present invention;

FIG. 8 is a cross-sectional view of a gas delivery assembly according to another embodiment of the present invention;

FIG. 9 is a cross-sectional view of a gas delivery assembly according to another embodiment of the present invention;

FIG. 10 is a cross-sectional view of a gas delivery assembly according to another embodiment of the present invention;

FIG. 11 is a cross-sectional view of a gas delivery assembly according to another embodiment of the present invention;

FIG. 12 is a cross-sectional view of a gas delivery assembly according to another embodiment of the present invention;

FIG. 13 is a cross-sectional view of a gas delivery assembly according to another embodiment of the present invention;

FIG. 14 is a cross-sectional view of a gas delivery assembly according to another embodiment of the present invention;

FIG. 15 is a cross-sectional view of a gas delivery assembly according to another embodiment of the present invention;

FIGS. 16A-16C are cross-sectional views of gas delivery assemblies according to embodiments of the present invention;

FIGS. 17A-17C are cross-sectional views of gas delivery assemblies according to other embodiments of the present invention;

FIGS. 18A-18C are cross-sectional views of gas delivery assemblies according to other embodiments of the present invention; and

FIGS. 19A-19C are cross-sectional views of gas delivery assemblies according to other embodiments of the present invention.

### DETAILED DESCRIPTION OF SEVERAL EMBODIMENTS OF THE INVENTION

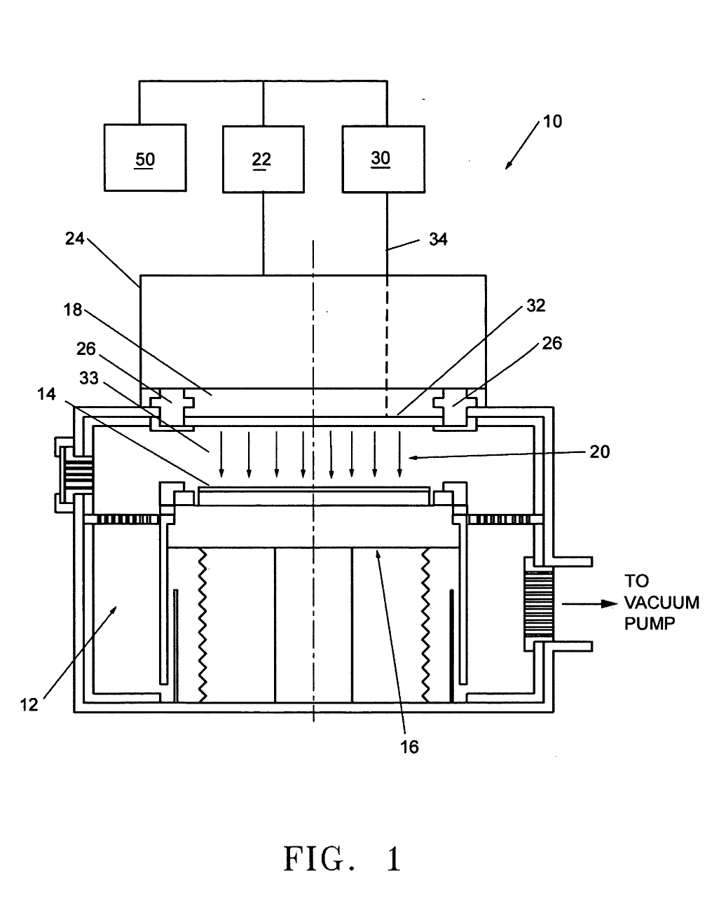

According to the present invention, process gas can be distributed in a profile as desired, e.g., uniformly distributed, form one or more gas supplies to a substrate positioned facing a gas delivery or gas injection assembly. The gas injection assembly can be used in any type of plasma processing apparatus to provide a distribution of gas over a surface of a workpiece such as a semiconductor substrate. Such apparatus includes chemical vapor deposition (CVD) systems, plasma etching systems, capacitively coupled plasma (CCP) reactors, inductively coupled plasma (ICP) reactors, electron cyclotron resonance (ECR) reactors, Helicon wave plasma reactors, and the like. In FIGS. 1-3 exemplary plasma reactors are shown using a gas delivery or injection assembly according to the present invention, however, one of ordinary skill in the art would appreciate that the gas injection assembly can be incorporated in any plasma apparatus that uses a gas in a plasma process.

Referring now to FIG. 1, a plasma reactor 10 is shown to include a plasma chamber 12 that functions as a vacuum processing chamber adapted to perform plasma etching from, material deposition on and/or chemical/mechanical alteration of a workpiece 14. The workpiece 14 can be, for example, a semiconductor substrate such as a silicon wafer. However, other types of substrates are also within the scope of the present invention. The plasma reactor 10 further includes chuck assembly 16 for holding the workpiece 14 and electrode assembly 18 for providing plasma energy to initiate the plasma. The chuck assembly 16 may be made movable to allow adjusting the distance between the chuck assembly 16 and the electrode assembly 18.

The electrode assembly 18 is arranged adjacent chuck assembly 16 to form plasma region 20. The electrode assembly 18 is capacitively coupled to the plasma when the workpiece 14 is being plasma processed, i.e. a capacitively coupled plasma (CCP) source assembly is used in plasma reactor 10. The plasma may have a plasma density (e.g., number of ions/volume, along with energy/ion) that is uniform, unless the density needs to be tailored to account for other sources of process non-uniformities or to achieve a desired process non-uniformity. In order to protect the electrode assembly 18 and other components from heat damage due to the plasma, a cooling system (not shown) in fluid communication with electrode assembly 18 may be included for flowing a cooling fluid to and from the electrode assembly 18.

Electrode assembly 18 may be electrically connected to an RF power supply system 22 via electrode impedance match network 24. The impedance match network matches the impedance of power supply system 22 to the impedance of the electrode assembly 18 and the associated excited plasma. In this way, the power may be delivered by the RF power supply to the electrode assembly 18 and the associated excited plasma with reduced reflection. Insulator 26 is also provided to electrically decouple the electrode assembly 18 and associated impedance match network 24 from the wall of the process chamber 12 to allow onset of a plasma in region 20 between electrode assembly 18 and chuck assembly 16. For example, insulator 26 can be formed of a substantially non-conductive material such as, but not limited to, Rexolite “Rexolite” is a registered trademark of C-Lee Plastics Company, Inc. that refers to a cross-linked polystyrene plastic), alumina, quartz, Teflon (“Teflon” is a registered trademark of E.I. du Pont de Nemours and Company that refers to polytetrafluoroethylene), and ceramics.

In addition, the chuck assembly 16 used to support the workpiece 14, substrate or wafer can also be provided with an RF power supply (not shown) coupled thereto to bias the wafer.

The plasma reactor 10 further includes a gas supply system 30 in pneumatic communication with plasma chamber 12 via one or more gas conduits 34 for supplying gas in a regulated manner to form the plasma. Gas supply system 30 can supply gases such as chlorine, hydrogen-bromide, octafluorocyclobutane, and various other fluorocarbon compounds, and for chemical vapor deposition applications supplies silane, tungsten-tetrachloride, titanium-tetrachloride, or the like. In the CCP source assembly, the gases may be injected through gas inject/delivery assembly 32 opposite the chuck assembly 16 holding the substrate or wafer. Channels interconnecting a showerhead array of gas injection orifices can be formed within the gas inject assembly 32 to allow the gases to flow into plasma region 20 as illustrated by arrows 33, for example. The gas injection assembly will be described in more detail in the following paragraphs.

The gases injected in the chamber 12 are evacuated using a vacuum pump (not shown) which can be a turbo molecular pump. In this way, the gaseous environment all around the chuck assembly 16 in the process chamber 12 and particularly in the plasma region 20 is pumped by the vacuum pump.

Plasma reactor 10 may further include a main control system 50 to which RF power supply system 22, gas supply system 30, and other devices are electronically connected. In one embodiment, main control system 50 is a computer having a memory unit MU having both a random access memory (RAM) and a read-only memory (ROM), a central processing unit CPU, and a hard disk HD, all in electronic communication. Hard disk HD serves as a secondary computer-readable storage medium, and may be for example, a hard disk drive for storing information corresponding to instructions for controlling plasma reactor 10. The control system 50 may also include a disk drive DD, electronically connected to hard disk HD, memory unit MU and central processing unit CPU, wherein the disk drive is capable of reading and/or writing to a computer-readable medium CRM, such as a floppy disk or compact disc (CD) on which is stored information corresponding to instructions for control system 50 to control the operation of plasma reactor 10.

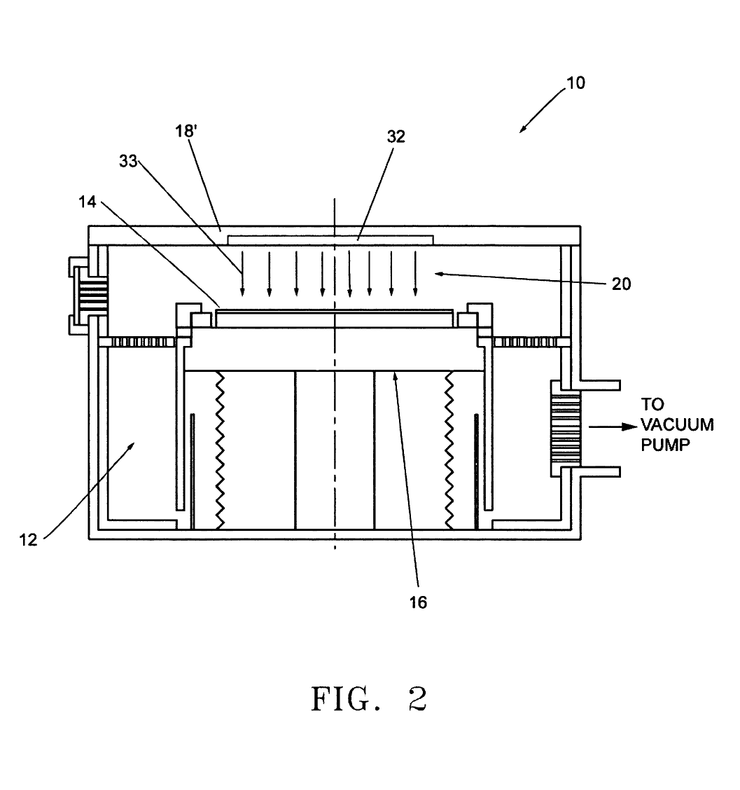

FIG. 2 is a cross-sectional view of a plasma reactor 10′ according to another embodiment of the present invention. This embodiment of the plasma reactor includes some of the same components of the first embodiment of plasma reactor except that in this embodiment the electrode assembly 18′ is connected to the ground and the chuck assembly 16 is biased with an RF voltage to allow onset of a plasma in plasma region 20.

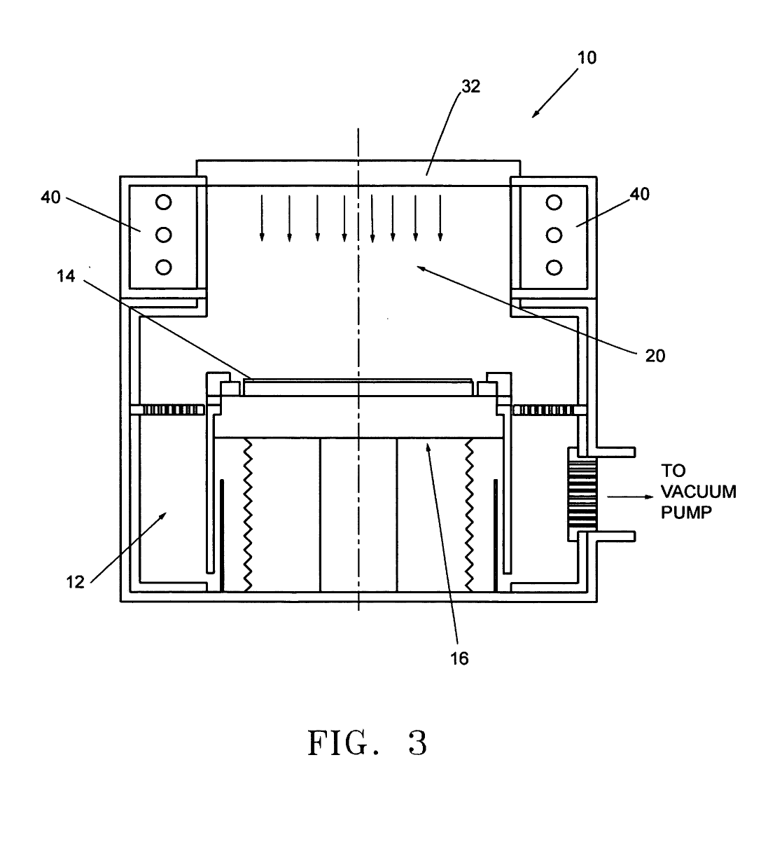

FIG. 3 is a cross-sectional view of a plasma reactor 10″ according to another embodiment of the present invention. This embodiment of the plasma reactor includes some of the same components of the first embodiment of plasma reactor except that in this embodiment an inductively coupled plasma (ICP) source 40 is used instead of a CCP source. Accordingly, the upper region of chamber 12 is adapted to include ICP source assembly 40, and a gas inject assembly 32. ICP source 40 can also include electrostatic shielding to form an electrostatically shielded radio frequency (ESRF) source. Regardless of the source of the RF energy, the plasma in the region 20 inside of the chamber 12 is excited by the RF energy that is generated by the respective RF power generators (not shown). In the ICP plasma source assembly, the gases may be injected through the gas inject assembly 32 opposite the chuck assembly 16 holding the substrate or wafer 14.

Although only capacitively coupled plasma (CCP) and inductively coupled plasma (ICP) sources have been described above, electron cyclotron resonance (ECR) reactors, Helicon wave plasma reactors, and the like can also be used. In fact, the gas injection assemblies described below can be incorporated in any plasma apparatus that uses a gas in a plasma process.

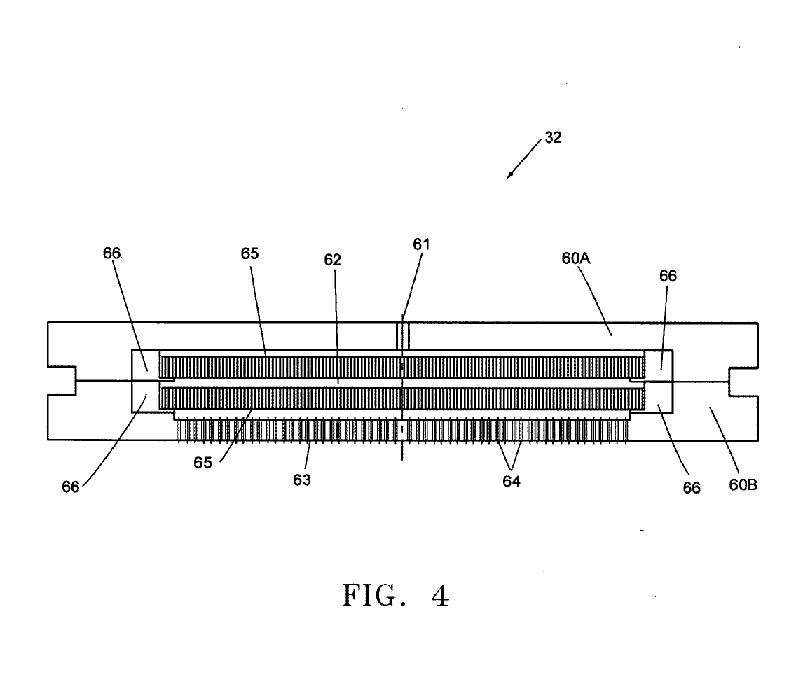

Referring now to FIG. 4, a cross-sectional view of a gas delivery/inject assembly 32 according to one embodiment of the present invention is shown. Gas delivery assembly 32 comprises a first plate 60A and a second plate 60B forming a gas plenum distribution chamber 62. As shown in FIG. 1, for example, the gas delivery assembly 32 may be electrically connected to the electrode assembly 18 by directly attaching the gas delivery assembly to the electrode assembly 18. Alternatively, the gas delivery assembly 32 can also be used as an electrode assembly by connecting the gas delivery assembly 32 to an RF power supply. In this instance, at least one of the first plate 60A and the second plate 60B is electrically connected to an RF power supply.

The first plate 60A has at least one gas inlet 61 for supplying gas to the gas plenum chamber 62. The gas inlet 61 can open into various portions of the plenum distribution chamber 62. For example, as shown in FIG. 4, the gas inlet 61 can supply the process gas through a central opening in a surface of the first pate 60A into a volume in the gas plenum.

The second plate 60B can include a gas showerhead injection plate 63 which has a plurality of holes 64 or the second plate 60B may be provided with the plurality of holes 64. The holes 64 in gas showerhead injection plate 63 allow the gas in plenum distribution chamber 62 to exit the gas delivery assembly 32 and to flow into plasma region 20 (shown in FIGS. 1-3).

The first plate 60A and the second plate 60B surround a baffle honeycomb core 65 disposed inside the plenum distribution chamber 62. The baffle honeycomb core 65 may be mounted to the first and second plates 60A and 60B by using, for example, mounting rings 66 or other attachment method such as bonding, welding or fastening.

The honeycomb panels are structures that are comprised of a plurality of tiny hexagonal (or other shape) cells. The honeycomb panels can be made, for example, from aluminum, however other materials can also be used to produce honeycomb structures. The cell size, i.e., width, depth of material, thickness of cell walls and grade of aluminum are all variable to suit specific requirements and tailored to impart the correct properties in the final manufactured units to achieve a desired flow of gas. For example, aluminum honeycomb is available in many different foil gauges from 0.0015 inch (0.0381 mm) to 0.006 inch (0.1524 mm). The honeycomb cell width dimensions range from about 0.06 inch (1.524 mm) to 0.365 inch (9.271 mm). The walls of the cells can also have micro perforations to allow movement of gas between adjacent cells to equalize pressure, for example, in environments with rapid pressure variations. Moreover, the honeycomb panels can be shaped or contoured to provide a desired cross-section. A more detailed discussion of the use of a honeycomb structure as a baffle can be found in a co-pending, commonly assigned U.S. provisional patent application No. 60/486,458 filed on Jul. 14, 2003, entitled “Method and Apparatus for Delivering Process Gas to a Process Chamber,” the entire contents of which are incorporated herein by reference.

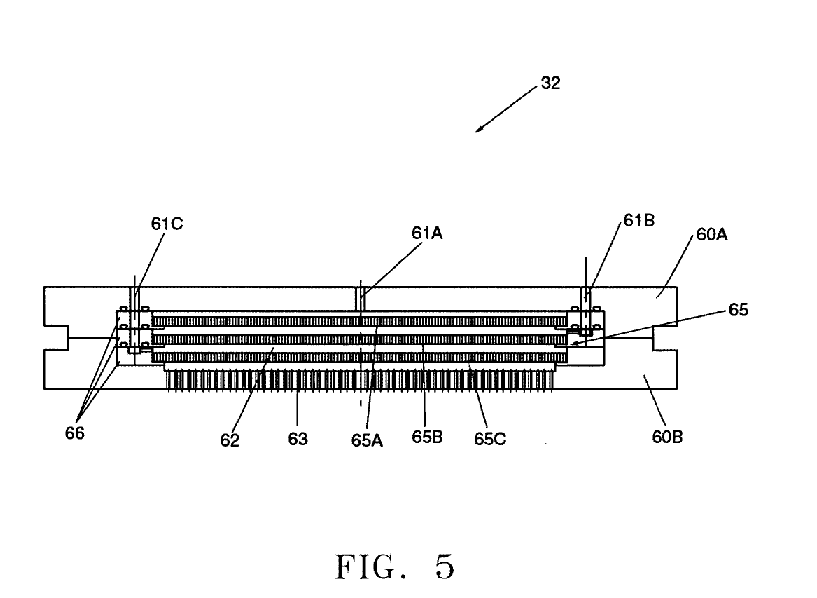

FIG. 5 shows a cross-sectional view of a gas delivery/inject assembly 32 according to another embodiment of the present invention. Gas delivery assembly 32 comprises essentially the same elements as the previous embodiment shown in FIG. 4. However, in this embodiment, the first plate 60A has a plurality of gas inlets 61A, 61B and 61C for supplying gas to the gas plenum chamber 62 and the honeycomb baffle 65 is formed of a plurality of spaced apart honeycomb panels, such as honeycomb panels 65A, 65B and 65C. Although the honeycomb baffle 65 is shown having three honeycomb panels 65A, 65B 65C, one of ordinary skill in the art would appreciate that any number of panels may be used.

The gas inlet can open into various portions of the plenum distribution chamber 62. For example, as shown in FIG. 5, the gas inlet 61A supplies gas through a central opening in a surface of the first plate 60A to the volume in the gas plenum distribution chamber 62 between the first plate 60A and the first honeycomb panel 65A constituting a portion of the honeycomb baffle 65. The gas inlet 61B supplies gas through a lateral opening in a surface of the first plate 60A to the volume in the gas plenum distribution chamber 62 between the first honeycomb panel 65A and the second honeycomb panel 65B. The gas inlet 61C supplies gas through a lateral opening in a surface of the first plate 60A to the volume in the gas plenum distribution chamber 62 between the second honeycomb panel 65B and the third honeycomb panel 65C.

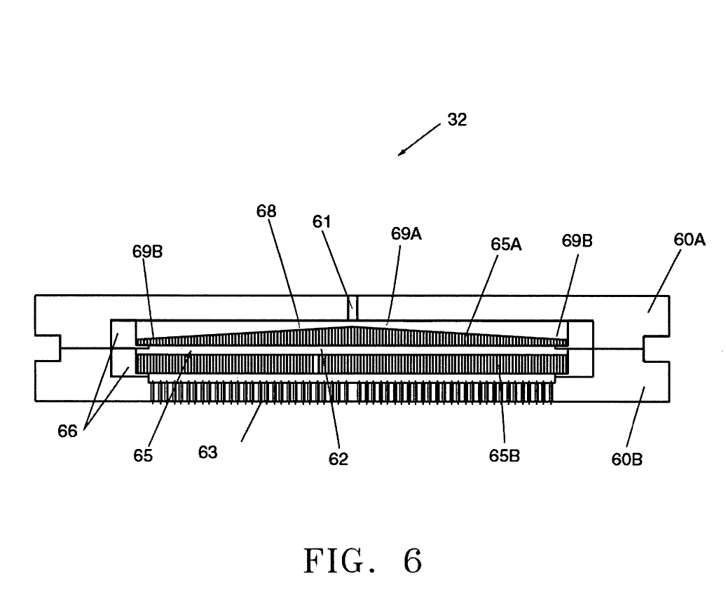

FIGS. 6-14 show cross-sectional views of gas delivery/inject assemblies 32 according to other embodiments of the present invention. Gas delivery assembly 32 comprises essentially the same elements as the previous embodiment shown in FIG. 4. The first plate 60A an the second plate 60B surround a baffle honeycomb core 65 disposed inside the plenum distribution chamber 62. The baffle honeycomb core 65 includes honeycomb panel 65A and honeycomb panel 65B. In these embodiments, however, one of the honeycomb panels and/or the plate surfaces has a contoured surface. The contoured surfaces, whether formed on the first plate 60A, the second plate 60B or honeycomb panels 65A and 65B, aid in creating a desired pressure distribution as the gas exits the baffle assembly 65 and proceeds through the inject plate 63 in to the plasma region 20 (shown in FIGS. 1-3). For instance, the shape or contour of a particular surface can be configured to deliver a pressure distribution to enhance a plasma process. Such pressure distribution can be, for example, a pressure that is substantially the same in each exit hole 64 in showerhead plate 63.

For example, FIG. 6 shows honeycomb panel 65A having a contoured surface 68. In this embodiment, the gas inlet 61 is located in the first plate 60A and supplies gas through a central opening in the first plate 60A to a volume in the gas plenum distribution chamber 62 between the first plate 60A and the first honeycomb panel 65A. The honeycomb panel 65A is thicker at its central portion 69A, i.e., in the vicinity of the gas inlet 61 and thinner at its outer portions or periphery 69B. Thus, in the portion 69A around the inlet 61 where the gas pressure is the highest, the openings of the cells of the honeycomb panels 65A around that portion 69A are longer.

Gas pressure losses due to friction and collisions of the gaseous particles with the walls of the individual cells of the honeycomb panel occur as the gas passes through the openings of the cells of the honeycomb panels. Generally, for equal sized openings, a cell having a longer depth creates a greater pressure loss due to friction than a shorter depth cell. A smaller diameter opening causes a greater reduction in gas pressure than an opening with a larger diameter.

Therefore, in the portion 69A around the inlet 61 where the gas pressure is the highest, the gas flow encounters greater flow resistance due to friction with the walls of the individual cells of the honeycomb in portion 69A than in portion 69B where the cells of the honeycomb panel are thinner. This lowers the pressure of the gas as it enters the volume between the honeycomb panel 65A and the honeycomb panel 65B around the portion 69A. Whereas, in the portion 69B where the pressure of the gas is lower, the gas flow encounters less flow resistance because the depth of the individual cells in portion 69B is smaller. As a result, the pressure of the gas as it enters the volume between the honeycomb panel 65A and the honeycomb panel 65B in the vicinity of the portion 69A. This results, for example, in substantially equalizing the gas pressure across the volume between the honeycomb panel 65A and honeycomb panel 65B. In other words, a relatively uniform distribution of gas pressure on the backside of the honeycomb panel 65B can be obtained.

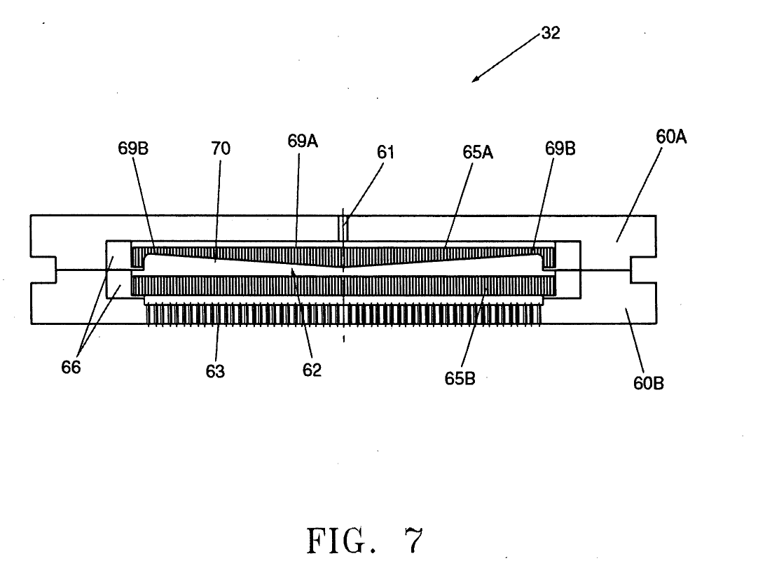

The embodiment shown in FIG. 7 is similar to the embodiment shown in FIG. 6, except that the contoured surfaces 70 is a lower surface of the honeycomb panel 65A. In this configuration, the gas inlet 61 opens into a central portion 69A of an upper portion of plenum chamber 62 between the first plate 60A and the honeycomb panel 65A. The honeycomb panel 65A is thicker in the middle portion 69A thereof and thinner in the outer portions 69B thereof. As a result, the openings of the honeycomb cells which are deeper in the portion 69A than in portion 69B are effective in reducing the gas pressure as the gas flows through the central portion 69A. Therefore, like the configuration shown in FIG. 6 wherein the contoured surface is an upper surface 68 of the honeycomb panel 65A, the configuration shown in FIG. 7 is also effective in obtaining a relatively uniform distribution of gas pressure on the backside of the honeycomb panel 65B.

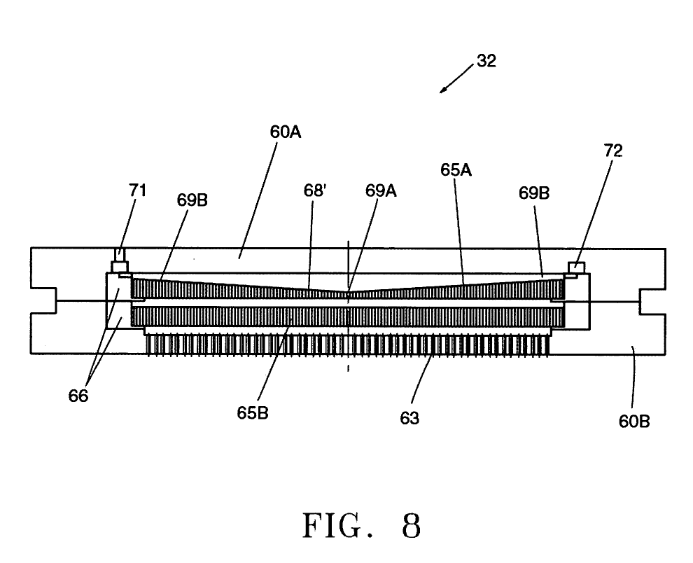

The embodiment shown in FIG. 8 is similar to the embodiment shown in FIG. 6. In this embodiment, however, the contoured surface 68′ located in the honeycomb panel 65A is such that the honeycomb panel 65A is thinner at its central portion 69A, and thicker at its outer portions or periphery 69B in the vicinity of the gas inlet 71.

In addition, the gas inlet 71, opens into an annular channel 72 extending around upper plenum between honeycomb panel 65A and first plate 60A whereby the gas enters peripheral region 69B. thus, the gas pressure is higher in the vicinity of annular channel 72 around the region 69B and the gas pressure becomes lower towards the central region in the portion 69A

Since the contoured surface 68′ of honeycomb panel 65A is thinner at its central portion 69A, and thicker at its outer portions or periphery 69B in the vicinity of annular channel 72, the pressure of the gas passing through the cells in the peripheral portions 69B of the honeycomb panel 65A is reduced when the gas reaches the volume between the honeycomb panel 65A and the honeycomb panel 65B. Whereas, the gas pressure of the gas passing through the cells in the central region 69A, which is in itially lower than the pressure of the gas passing through the cells of the peripheral region 619B, is not lowered as much. This results in providing a more uniform distribution of gas pressure on the backside of honeycomb panel 65B and hence an even more uniform distribution of gas pressure when the gas exits the showerhead injection plate 63.

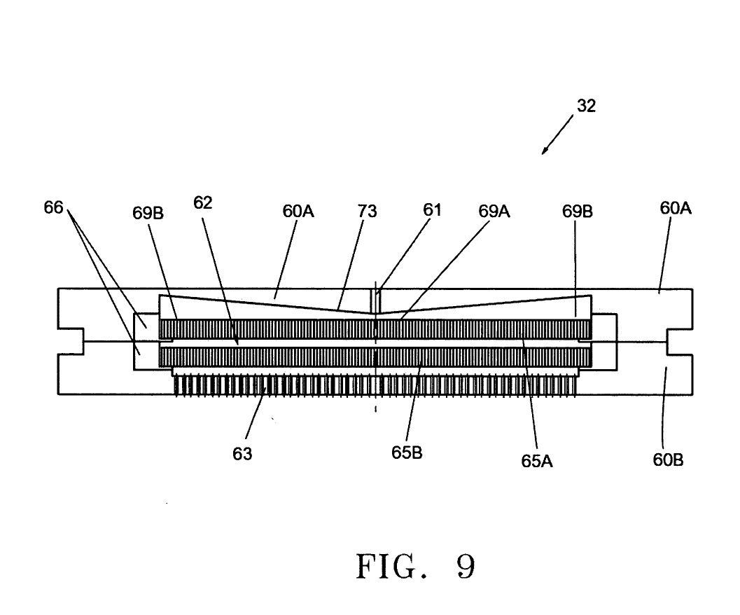

FIG. 9 shows a gas delivery/inject assembly 32 according to another embodiment of the present invention. Gas delivery assembly 32 comprises the same elements as the previous embodiments. In this embodiment, the gas inlet 61, is located in the first plate 60A and supplies gas through a central opening in the first plate 60A to the volume in the gas plenum distribution chamber 62 between the first plate 60A and the first honeycomb panel 65A. In this embodiment, however, the contoured surface 73 is located in the first plate 60A. The contoured surface 73 is convex, i.e., pointed, towards the honeycomb panel 65A such that gas pressure in central region 69A in the vicinity of the peripheral region 69B. Therefore, the gas pressure is not uniform across he surface of the honeycomb panel 65A. this is because the gas expands into the volume between the first plate 60A and the honeycomb panel 65A, towards the periphery of the honeycomb panel 65A which is bigger than the volume directly under the gas inlet 61.

Since the cells of the honeycomb panel 65A are of the same shape and size, the pressure of the gas passing through the cells in the honeycomb panel 65A and reaching the volume between the honeycomb panel 65A and honeycomb panel 65B will remain substantially unchanged. Consequently, the gas pressure which is initially not uniform across the backside surface of the honeycomb panel 65A will remain not uniform after passing through the honeycomb panel 65B. This trend continues even after the gas exits the showerhead injection plate 63.

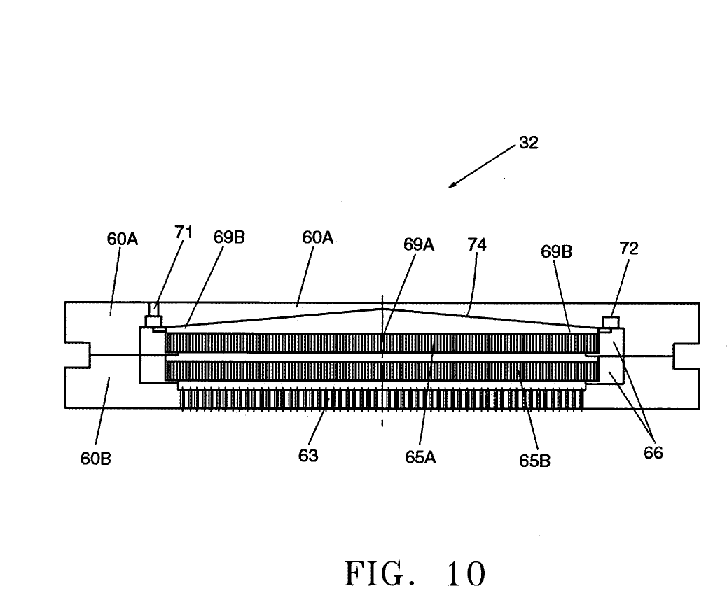

FIG. 10 shows a gas delivery/inject assembly 32 according to another embodiment of the present invention. Gas delivery assembly 32 comprises the same elements as the previous embodiments. In this embodiment, similarly to the embodiment shown in FIG. 8, the gas inlet 71 opens into an annular channel 72 extending around upper plenum between honeycomb panel 65A and first plate 60A whereby the gas enters peripheral region 69B. Thus, the gas pressure is highest in the vicinity of annular channel 72 around the region 69B and the gas pressure becomes lower towards the central region in the portion 69A.

In this embodiment, however, the contoured surface 74 is located in the first plate 60A and is concave relative to the honeycomb panel 65A such that the gas pressure in central region 69A in the vicinity of the gas inlet 61 is lower than the gas pressure in the vicinity of the peripheral region 69B. Therefore, the gas pressure is not uniform across the surface of the honeycomb panel 65A. This is because the gas expands into the volume between the first plate 60A and the honeycomb panel 65A, around the central region 69A, which is bigger than the volume directly under the annular channel 72.

Since the cells of the honeycomb panel 65A are of the same shape and size, the pressure of the gas passing through the cells in the honeycomb panel 65A and reaching the volume between the honeycomb panel 65A and honeycomb panel 65B will remain substantially unchanged. Consequently, the gas pressure which is initially not uniform across the backside surface of the honeycomb panel 65A will remain not uniform after passing through the honeycomb panel 65B. This trend continues even after the gas exits the showerhead injection plate 63.

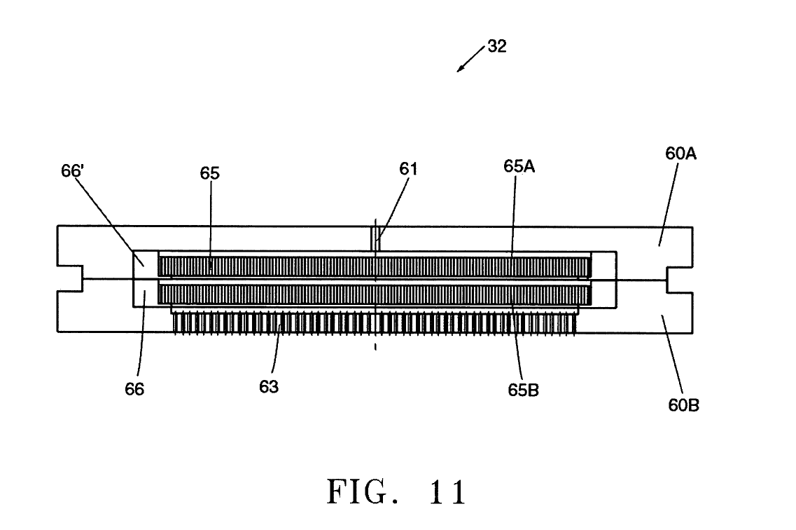

FIG. 11 shows a gas delivery/inject assembly 32 according to another embodiment of the present invention. The embodiment shown in FIG. 11 is similar to the embodiment shown in FIG. 4, except that the baffle honeycomb core 65, comprised of honeycomb panel 65A and honeycomb panel 65B, is mounted to the first and second plates 60A and 60B by using, for example, mounting rings 66 and 66′. One or both of the mounting rings 66 or 66′ is not completely machined away in the center region. Instead of a large hole forming the center of the ring, various shapes may be cut out leaving some material of the ring to support the honeycomb core 65 in the central region. The ring material that remains can be made small so as not to partially or completely block a large number of cells of the honeycomb core material so as to not hinder the flow of gas across the area of the honeycomb core. Alternatively, specific areas of the mounting rings 66 and 66′ can be cut out with a desired geometry to create a particular non-uniform pressure distribution. Thus, depending on the geometry of the mounting ring the pressure distribution can be tailored for a specific application.

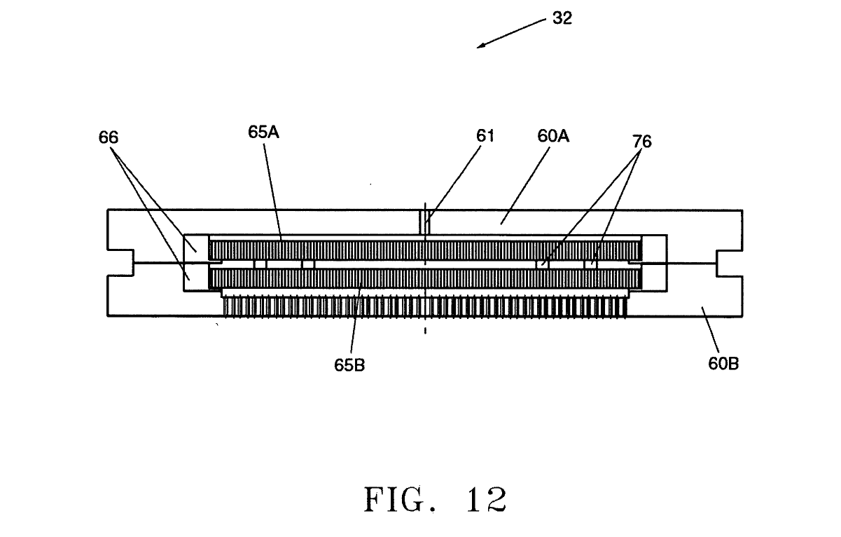

In other embodiments, such as in the arrangement shown in FIG. 12, one can also use a plurality of separate rings or plugs 76 or other shapes to separate different panels of honeycomb core material, such as honeycomb panel 65A and honeycomb panel 65B. This arrangement may be useful where lower panels of honeycomb core material are constructed from a thicker gauge to provide support for other layers or panels of honeycomb core material fabricated from a thinner gauge that is not rigid enough to support itself.

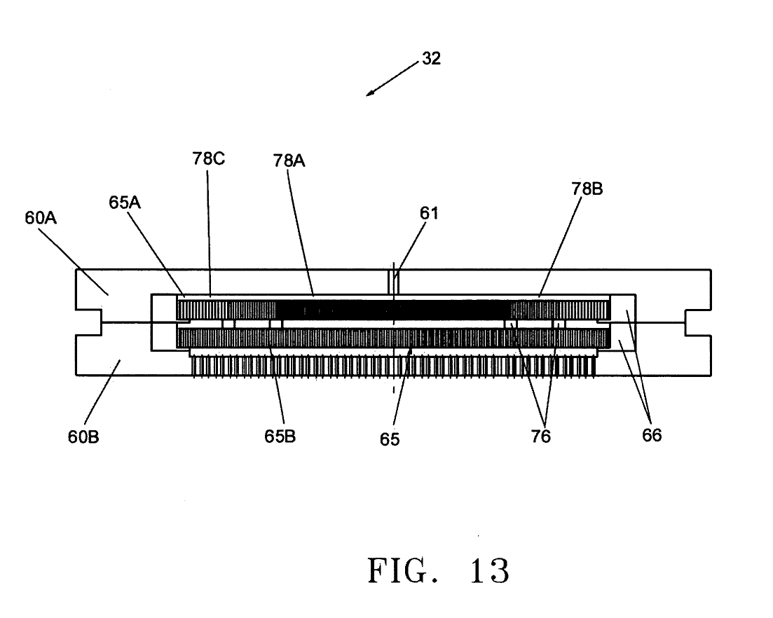

FIG. 13 shows a gas delivery/inject assembly 32 according to another embodiment of the present invention. Similarly to the embodiment shown in FIG. 4, the gas inject assembly 32 includes, among other things, a honeycomb core 65 disposed between first plate 60A and second plate 60B. The honeycomb core 65 comprises honeycomb panel 65A and honeycomb panel 65B. In this embodiment, however, honeycomb panel 65A is made of various cell sizes and/or different material gauges. For example, the honeycomb panel 65A can be formed of three honeycomb sections 78A-C. Section 78A has a small cell size, section 78B has a medium cell size and section 78C has a large cell size. Sections 78A-C are disposed in a radial fashion with the section 78A being the central portion (a disk, for example) of honeycomb panel 65A and the sections 78B and C being the peripheral portions of honeycomb panel 65A (forming annular sections around disk 78A).

In this way, the section of the honeycomb panel which has smaller cell size, i.e., section 78A, can be disposed facing the gas inlet 61 where the gas pressure is the highest, to reduce the pressure of the gas after passage through section 78A. While the sections of the honeycomb with a gradually larger size, i.e. sections 78B and 78C, can be disposed in regions where the gas pressure is lower. Hence, the various sections 78A-C compensate for the difference in gas pressure and homogenize the gas pressure distribution at the exit of honeycomb panel 65A. Different honeycomb core material can be arranged to compensate for gas inlet location to create a uniform or a non-uniform pressure distribution depending on the intended application.

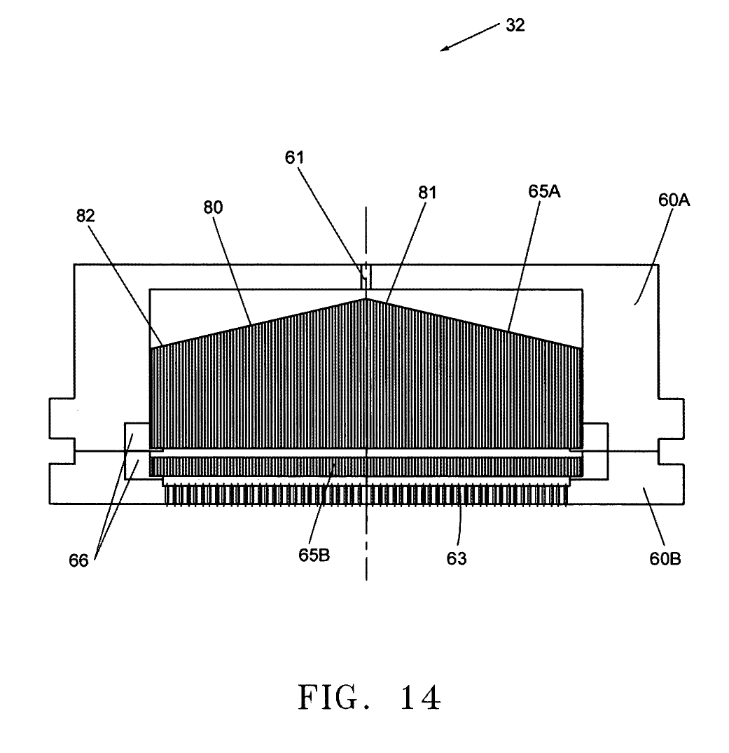

In another embodiment of the gas delivery/inject assembly 32 shown in FIG. 14, the honeycomb panel 65A is made thicker to create, for example, a uniform distribution of gas pressure. In the gas delivery assembly 32 the first plate 60A is modified to accommodate the thicker honeycomb panel 65A. For example, as shown in FIG. 14, the first plate 60A is shaped such that the cavity formed by the first plate 60A encloses the honeycomb panel 65A.

In FIG. 14, the honeycomb panel 65A is also shown having a contoured surface 80. The contoured surface 80 of honeycomb panel 65A is thicker at its central portion 81 in the vicinity of gas inlet 61, and thinner at its outer portions or periphery 82. Hence, the openings of the cells of the honeycomb panel 65A are longer around portion 81 and shorter around the peripheral portion 82. As a result, the gas pressure of the gas passing through the cells in the central portion 81 of the honeycomb panel 65A is reduced when the gas reaches the volume between the honeycomb panel 65A and honeycomb panel 65B. While the pressure of the gas passing through the cells in the peripheral regions 82, which is initially lower than the pressure of the gas passing through the cells of the central region 81, is not lowered as much. This allows a more uniform distribution of gas pressure on the backside of honeycomb panel 65B and hence an increased uniform distribution of gas pressure when the gas exits the showerhead injection plate 63.

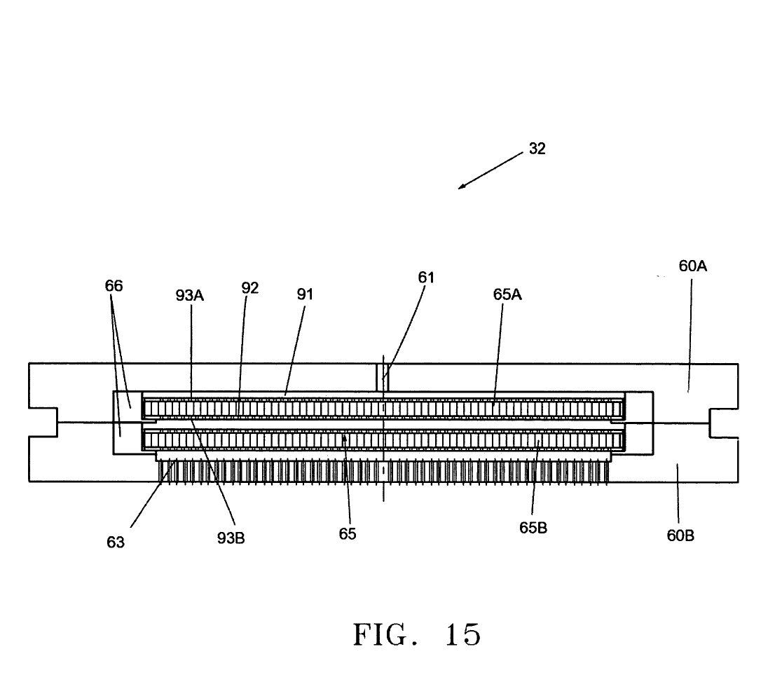

FIG. 15 shows a gas delivery/inject assembly 32 according to another embodiment of the present invention. The gas inject assembly 32 includes, among other things, a honeycomb core 65 disposed between first plate 60A and second plate 60B. The honeycomb core 65 comprises honeycomb panel 65A and honeycomb panel 65B. For example, honeycomb panels 65A can be covered on one or both of its surfaces with respectively layers 91 and 92 of material which can be made of the same material as the honeycomb panel or a different material. Layer 91 may comprise a plurality of inlet holes 93A and layer 92 may comprise a plurality of outlet or exit holes 93B. Inlet holes 93A and exit holes 93B may or may not be aligned relative to each other.

Each of the plurality of holes may or may not be associated with a cell in the honeycomb panel 65A. Inlet and outlet holes can be disposed at selected areas in the surface of honeycomb panel to provide selective reduction of gas pressure in specific areas of the honeycomb panel. Moreover, cells that do not have corresponding inlet and/or exit holes may be provided with venting holes to adjacent cells to allow the gas to escape laterally. In any case, venting holes can be provided to homogenize the flow of gas through the cells of the honeycomb panels. Although the inlet and exit holes have been described in reference to honeycomb panel 65A, it is equally possible to provide inlet and exit holes to the surface layers of honeycomb panel 65B.

Although one honeycomb panel is shown in the Figures being contoured, one of ordinary skill in the art would appreciate that more than one honeycomb panels may be contoured. Similarly, although the contour of the surface of the honeycomb panel is shown as a conical shape, one of ordinary skill in the art would appreciate that other shapes or contours such as paraboloid or other shape is also within the scope of the present invention. The many features and advantages of the present invention are apparent from the detailed specification and thus, it is intended by the appended claims to cover all such features and advantages of the described apparatus which follow the true spirit and scope of the invention.

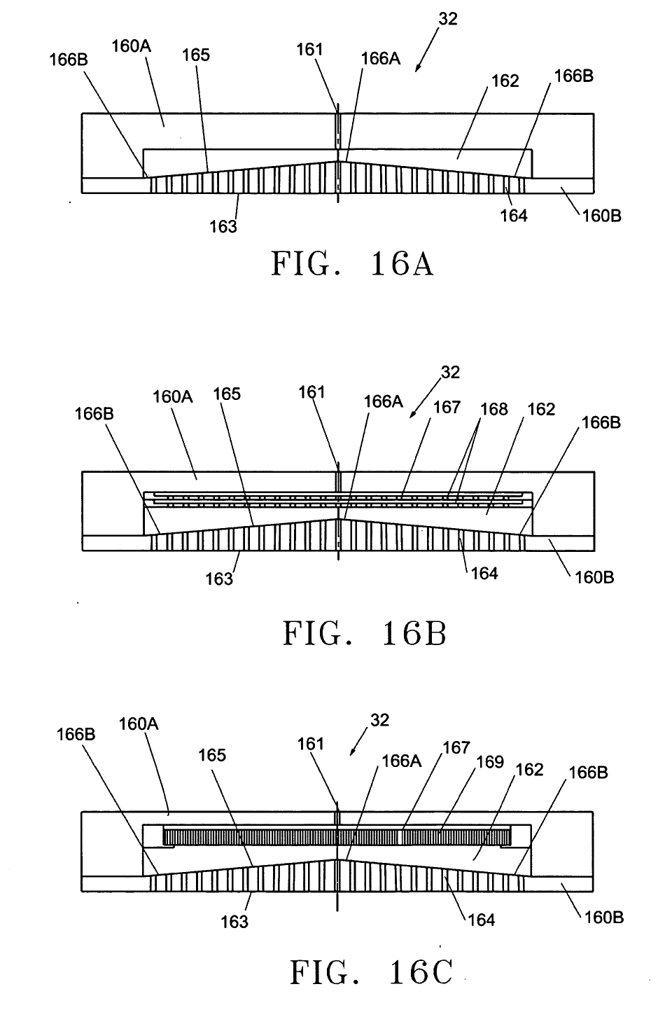

Referring now to FIGS. 16A-16C, cross-sectional views of a gas delivery/inject assembly 32 according to embodiments of the present invention are shown. Gas delivery assembly 32 comprises a first plate 160A and a second plate 160B forming a gas plenum distribution chamber 162. As shown in FIG. 1, for example, the gas delivery assembly 32 may be electrically connected to the electrode assembly 18 by directly attaching the gas delivery assembly to the electrode assembly 18. Alternatively, the gas delivery assembly 32 can also be used as an electrode assembly by connecting the gas delivery assembly 32 to an RF power supply. In this instance, at least one of the first plate 160A and the second plate 160B is electrically connected to an RF power supply.

The first plate 160A has at least one gas inlet 161 for supplying gas to the gas plenum chamber 162. The gas inlet can open into various portions of the plenum distribution chamber 162. For example, as shown in FIGS. 16A-16C, the gas inlet 161 can supply the process gas through a central opening in a surface of the first plate 160A into a volume in the gas plenum.

The second plate 160B can include a gas showerhead injection plate 163 which has a plurality of holes 164 or the second plate 160B may be provided with the plurality of holes 164. The holes 164 in gas showerhead injection plate 163 allow the gas in plenum distribution chamber 162 to exit the gas delivery assembly 32 and to flow into plasma region 20 (shown in FIGS. 1-3).

As shown in FIGS. 16A-16C, the injection plate 163 has a surface 165 which is shaped to create a desired pressure distribution as the gas exits the injection plate 163 to enter into the plasma region 20 (shown in FIGS. 1-3). For instance, the shape or contour of a surface 165 can be configured to deliver a pressure distribution to enhance a plasma process. Such pressure distribution can be, for example, a pressure that is substantially the same at the exit of each hole 164 in showerhead plate 163. The holes 164 can also be distributed on the surface 165 to allow gas in the gas plenum chamber 162 to exit the gas delivery assembly 32 with a substantially uniform pressure. In addition, the cross section of the holes can be tailored to affect the distribution of pressure of the gas when exiting the gas delivery assembly 32. The cross section of the holes can be, for example, circular, elliptical, polygonal or the like. One can also select a specific cross-section size for each hole 164 depending on the location of the hole on the surface 165 in order to affect the distribution of gas pressure at the exit of gas delivery assembly 32.

The gas inlet 161 is located in the first plate 160A and supplies gas through a central opening in the first plate 160A to a volume in the gas plenum distribution chamber 162 between the first plate 160A and the second plate 160B. The surface 165 of injection plate 163 is contoured such that the injection plate 163 is thicker at its central portion 166A, i.e., in the vicinity of the gas inlet 161, and thinner at its outer portions or periphery 166B. Thus, in the portion 166A around the inlet 161 where the gas pressure is the highest, the openings of holes 164 around that portion 166A are longer.

Gas pressure losses due to friction and collisions of the gaseous particles with the walls of the individual holes of gas injection plate 163 occur as the gas passes through the holes 164. Generally, for equal sized holes or openings, a hole with a longer depth creates a greater pressure loss due to friction than a shorter depth hole. A smaller diameter hole or a hole with a smaller size cross-section causes a greater reduction in gas pressure than a hole with a larger diameter or a larger size cross-section.

Therefore, in the portion 166A around the inlet 161 where the gas pressure is the highest, the gas flow encounters greater flow resistance due to friction with the walls of the individual holes 164 of the injection plate in portion 166A than in portion 166B where the holes of the injection plate are thinner. This lowers the pressure of the gas as it exits the injection plate 163. Whereas, in the portion 166B where the pressure of the gas is lower, the gas flow encounters less flow resistance because the depth of the holes in the portion 166B is smaller. As a result, the pressure of the gas as it exits the injection plate 163 in the vicinity of the portion 166B is not reduced as much as the pressure of the gas in the vicinity the portion 166A. This results, for example, in substantially equalizing the gas pressure at the exit of injection plate 163 before reaching the plasma region 20 (shown in FIGS. 1-3). In other words, a relatively uniform distribution of gas pressure can be obtained in the plasma region 20.

The gas delivery assembly 32 may further comprise a gas baffle assembly disposed in the a gas plenum distribution chamber 162 between the first plate 160A and the second plate 160B. For example, in the embodiment shown in FIG. 16A, the gas delivery is not provided with a gas baffle assembly, whereas in the embodiments shown in FIGS. 16B and 16C, the gas delivery assembly comprises a gas baffle assembly 167.

The gas baffle assembly 167 can comprise one or more gas baffle plates 168, as shown in FIG. 4B or can include one or more honeycomb panels 169, as shown in FIG. 16C. Similar to the gas injection plate 163, the gas baffle plates 168 are provided with a plurality of holes and the holes may have different diameters and sizes and can be distributed on the gas baffle plates 168 to affect the pressure distribution of the gas at the exit of gas baffle assembly 167.

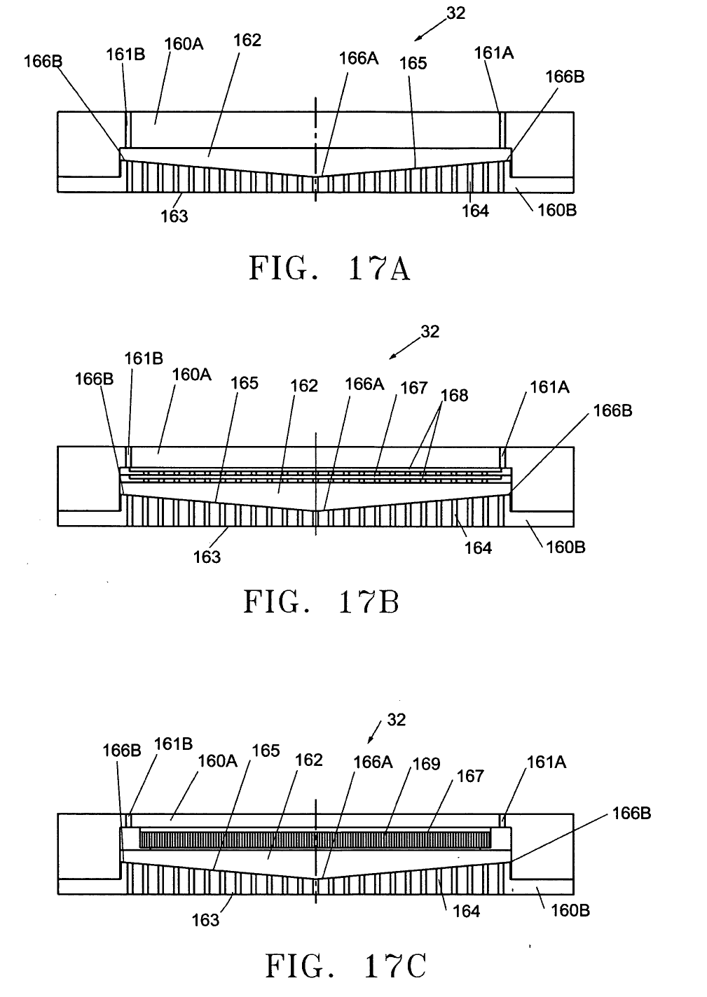

FIGS. 17A-17C show cross-sectional views of a gas delivery/injection assembly 32 according to other embodiments of the present invention. Gas delivery assembly 32 comprises essentially the same elements as the previous embodiments shown in FIGS. 16A-16C. However, in these embodiments, the first plate 160A has a plurality gas inlets 161A and 161B for supplying gas to the gas plenum chamber 162.

The gas inlets 161A and 1611B can open into various portions of the plenum distribution chamber. For example, as shown in FIGS. 17A-17C, the gas inlet 161A and the gas inlet 161B both supply gas through a lateral opening in a surface of the first plate 160A to the volume in the gas plenum distribution chamber 162 between the first plate 160A and the second plate 160B comprising injection plate 163.

Similarly to the embodiments shown in FIGS. 16A-16C, the shower plate or injection plate 163 has a contoured surface 165. However, in these embodiments, the contoured surface 165 of the shower head plate 163 is such that the injection plate 163 is thinner at its central portion 166A, and thicker at its outer portions or periphery 166B in the vicinity of the gas inlets 161A and 161B. The gas inlets 161A and/or 161B can also open into an annular channel (not shown) extending around upper plenum between first plate 160A and second plate 160B whereby the gas enters peripheral region 166B. Thus, the gas pressure is higher in the vicinity of gas inlets 161A and 161B or in the vicinity of the annular channel around the region 166B and the gas pressure becomes lower towards the central region in the portion 166A.

Since the contoured surface 165 of injection plate 163 is thinner at its central portion 166A, and thicker at its outer portions or periphery 166B in the vicinity of gas inlets 161A and 161B or in the vicinity of the annular channel, the pressure of the gas passing through the holes 164 in the peripheral portions 166B of the injection plate 163 is reduced. Whereas, the gas pressure of the gas passing through the holes 164 in the central region 169A, which is initially lower than the pressure of the gas passing through the holes of the peripheral region 166B, is not lowered as much. This results in providing a more uniform distribution when the gas exits the showerhead injection plate 163.

Similarly to the embodiments shown in FIGS. 16A- 1 6C, the gas delivery assembly 32 may further comprise a gas baffle assembly disposed in the gas plenum distribution chamber 162 between the first plate 160A and the second plate 160B. For example, in the embodiment shown in FIG. 17A, the gas delivery is not provided with a gas baffle assembly, whereas in the embodiments shown in FIGS. 17B and 17C, the gas delivery assembly comprises a gas baffle assembly 167.

The gas baffle assembly 167 may comprise one or more gas baffle plates 168, as shown in FIG. 17B or can include one or more honeycomb panels 169, as shown in FIG. 17C. Similarly to the gas injection plate 163, the gas baffle plates 168 are provided with a plurality of holes and the holes may have different diameters and can be distributed on the gas baffle plates 168 to affect the pressure distribution of the gas at the exit of gas baffle assembly 167. Similarly, honeycomb panels 169 may also be selected to affect the pressure distribution of the gas at the exit of the gas baffle assembly 167.

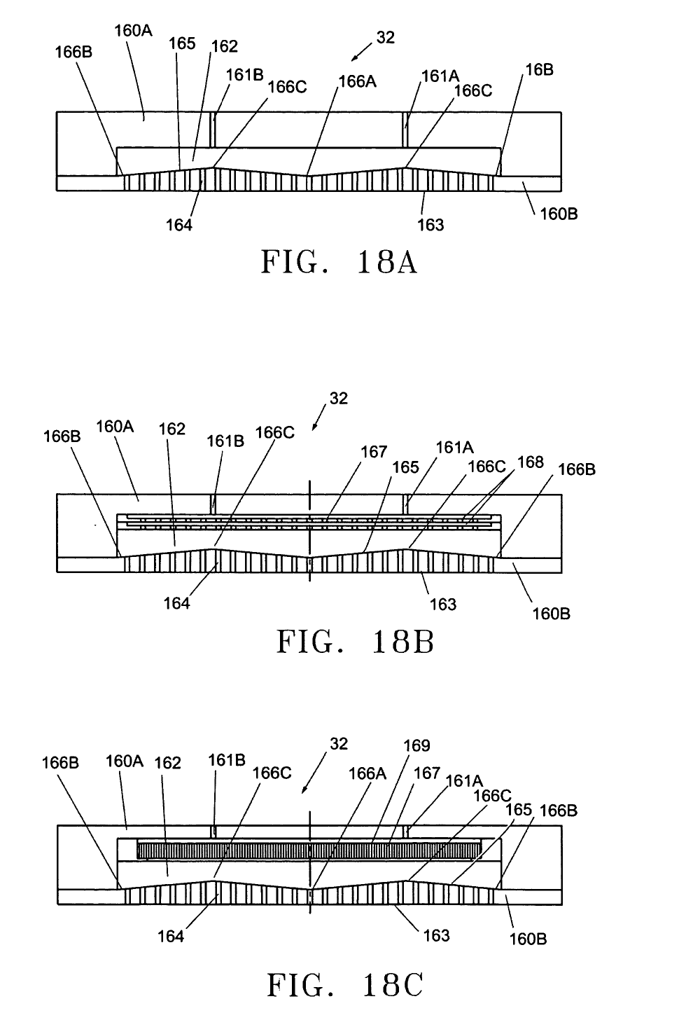

FIGS. 18A-18C show cross-sectional views of a gas delivery/injection assembly 32 according to other embodiments of the present invention. Gas delivery assembly 32 comprises essentially the same elements as the previous embodiments shown in FIGS. 17A-17C. However, in these embodiments, the plurality of gas inlets 161A and 161B for supplying gas to the gas plenum chamber 162 are positioned at a distance from the center of the first plate 160A but away from the periphery of the first plate 160A.

Similarly to the embodiments shown in FIGS. 17A-17C, the shower plate or injection plate 163 has a contoured surface 165. However, in these embodiments, the contoured surface 165 of the shower head plate 163 is such that the injection plate 163 is thinner at its central portion 166A and at its outer portions or periphery 166B, but thicker at portions 166C located between portions 166A and 166B, directly under or in the vicinity of the gas inlets 161A and 161B. Thus, the gas pressure is higher in the vicinity of gas inlets 161A and 161B around the region 166C while the gas pressure becomes lower towards the central region in the portion 166A and also towards the periphery in the portion 166B.

Since the contoured surface 165 of injection plate 163 is thinner at its central portion 166A and outer portions 166B, but thicker in the vicinity of gas inlets 161A and 161B, the pressure of the gas passing through the holes 164 in the portions 166C of the injection plate 163 is reduced. Whereas, the gas pressure of the gas passing through the holes 164 in the central region 166A and peripheral region 166B, which is initially lower than the pressure of the gas passing through the holes of the region 166C, is not lowered as much. This results in providing a more uniform distribution when the gas exits the showerhead injection plate 163.

Similarly to the embodiments shown in FIGS. 17A-17C, the gas delivery assembly 32 may further comprise a gas baffle assembly disposed in the gas plenum distribution chamber 162 between the first plate 160A and the second plate 160B. For example, in the embodiment shown in FIG. 18A, the gas delivery is not provided with a gas baffle assembly, whereas in the embodiments shown in FIGS. 18B and 18C, the gas delivery assembly comprises a gas baffle assembly 167.

The gas baffle assembly 167 can comprise one or more gas baffle plates 168, as shown in FIG. 18B or can include one or more honeycomb panels 169, as shown in FIG. 17C. The gas baffle plates 168 are provided with a plurality of holes and the holes may have different diameters and can be distributed on the gas baffle plates 168 to affect the pressure distribution of the gas at the exit of gas baffle assembly 167. Honeycomb panels 169 may also be selected to affect the pressure distribution of the gas at the exit of the gas baffle assembly 167.

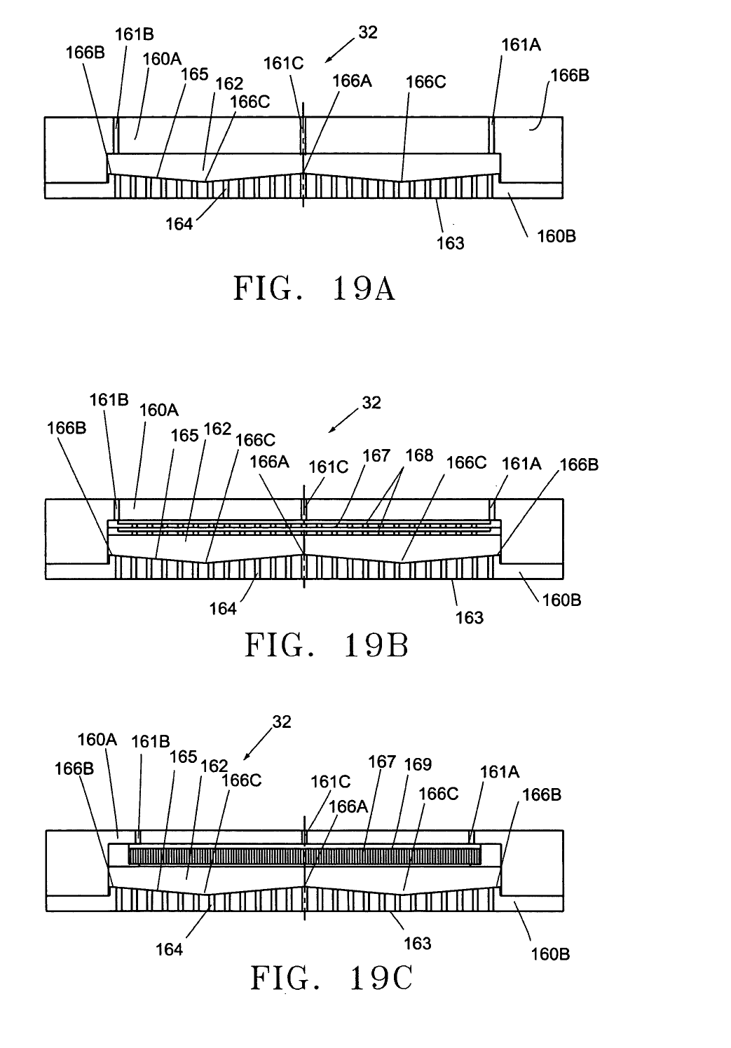

FIGS. 19A-19C show cross-sectional views of a gas delivery/injection assembly 32 according to other embodiments of the present invention. Gas delivery assembly 32 comprises essentially the same elements as the previous embodiments. However, in these embodiments, the first plate 160A has a plurality gas inlets 161A, 161B and 161C for supplying gas to the gas plenum chamber 162.

The gas inlets 161A, 161B and 161C can open into various portions of the plenum distribution chamber. For example, as shown in FIGS. 19A-19C, the gas inlet 161A and the gas inlet 161B both supply gas through a lateral opening in a surface of the first plate 160A to the volume in the gas plenum distribution chamber 162 between the first plate 160A and the second plate 160B. The gas inlet 161C supply gas through a central opening in a surface of the first plate 160A to the volume in the gas plenum chamber 62 between the first plate 160A and second plate 160B. The second plate 160B includes the injection plate 163.

The shower plate or injection plate 163 has a contoured surface 165. However, in these embodiments, the contoured surface 165 of the shower head plate 163 is such that the injection plate 163 is thicker at its central portion 166A and at its outer portions or periphery 166B, but thinner at portions 166C located between the periphery 166B and the central region 166A. Thus, the gas pressure is higher in the vicinity of gas inlets 161A, 161B around the region 166B as well as in the vicinity of gas inlet 161C around the central region 166A. However, the gas pressure tends to become lower towards the region in the vicinity of portion 166C because of the availability of more volume in that region and also because portion 166C is located relatively away from gas inlets 161A, 161B and 161C.

Since the contoured surface 165 of injection plate 163 is thicker at its central portion 166A and outer portions 166B, but thinner in the region 166C, the pressure of the gas passing through the holes 164 in the portions 166A and 166B of the injection plate 163 is reduced. Whereas, the pressure of the gas passing through the holes 164 in the central region 166C, which is initially lower than the pressure of the gas passing through the holes of the region 166A and 166B, is not lowered as much. This results in providing a more uniform distribution when the gas exits the showerhead injection plate 163.

Similarly to the previously described embodiments, the gas delivery assembly 32 may further comprise a gas baffle assembly disposed in the gas plenum distribution chamber 162 between the first plate 160A and the second plate 160B. For example, in the embodiment shown in FIG. 19A, the gas delivery is not provided with a gas baffle assembly, whereas in the embodiments shown in FIGS. 19B and 19C, the gas delivery assembly comprises a gas baffle assembly 167.

The gas baffle assembly 167 can comprise one or more gas baffle plates 168, as shown in FIG. 19B or can include one or more honeycomb panels 169, as shown in FIG. 19C. The gas baffle plates 168 are provided with a plurality of holes and the holes may have different diameters and can be distributed on the gas baffle plates 168 to affect the pressure distribution of the gas at the exit of gas baffle assembly 167. Honeycomb panels 169 may also be selected to affect the pressure distribution of the gas at the exit of the gas baffle assembly 167. For example, the gas baffle assemble aid in homogenizing the pressure of the gas before reaching the surface 165 of the injection plate 163. This provides an additional control of the gas pressure distribution.

Although the contour of the surface of the injection plate is shown as a conical shape, one of ordinary skill in the art would appreciate that other shapes or contours such as paraboloid, spherical or other shape is also possible.

Although the embodiments of the gas delivery assembly described above tend to improve the uniformity of the gas distribution. The gas inlet(s) in the gas delivery assembly, the shape of the injection plate and the holes in the injection plate can be also formed and positioned to create any desired gas distribution.

Since numerous modifications and changes will readily occur to those of skill in the art, it is not desired to limit the invention to the exact construction and operation described herein. Moreover, the process and apparatus of the present invention, like related apparatus and processes used in the plasma reactor arts tend to be complex in nature and are often best practiced by empirically determining the appropriate values of the operating parameters or by conducting computer simulations to arrive at a best design for a given application. Accordingly, all suitable modifications and equivalents should be considered as falling within the spirit and scope of the invention.

1. A gas delivery assembly for a plasma apparatus, comprising:
a first plate having a gas inlet;
a second plate having a plurality of holes, said second plate being coupled to said first plate and spaced apart from first said plate to form a plenum chamber; and
a baffle honeycomb core assembly disposed between said first plate and said second plate inside said plenum chamber.

2. A gas delivery assembly as recited in claim 1,
wherein said gas inlet supplies gas into said plenum chamber.

3. A gas delivery assembly as recited in claim 1,
wherein said gas inlet opens into various portions of said plenum chamber.

4. A gas delivery assembly as recited in claim 1,
wherein said gas inlet supplies gas through a central opening in said first plate.

5. A gas delivery assembly as recited in claim 1,
wherein said gas inlet supplies gas through a plurality of openings in said first plate.

6. A gas delivery assembly as recited in claim 1,
wherein said gas inlet supplies process gas through an annular channel which opens to an outer portion of said baffle honeycomb core assembly.

7. A gas delivery assembly as recited in claim 1,
wherein said baffle honeycomb core assembly includes at least one honeycomb panel.

8. A gas delivery assembly as recited in claim 7,
wherein said honeycomb panel comprises a plurality of cells.

9. A gas delivery assembly as recited in claim 8,
wherein said cells have varying sizes and said cells are arranged to control a distribution of gas pressure in said plenum chamber.

10. A gas delivery assembly as recited in claim 9,
wherein said cells are arranged such that cells with a smaller size are disposed in regions of said plenum chamber where gas pressure is higher and cells with larger size are disposed in regions of said plenum chamber where gas pressure is lower.

11. A gas delivery assembly as recited in claim 9,
wherein said sizes vary from smaller size at a central portion of said honeycomb panel to a larger size at the outer portion of said honeycomb panel.

12. A gas delivery assembly as recited in claim 7, further comprising attachments, wherein said at least one honeycomb panel is mounted to said first and second plates by using said attachments.

13. A gas delivery assembly as recited in claim 12,
wherein said attachments include at least one of a mounting ring, bonding, welding and fastening.

14. A gas delivery assembly as recited in claim 13,
wherein said attachments comprise said mounting ring, and said mounting ring comprises a structure cut out with a desired geometry to create a desired pressure distribution of the gas at an exit of said holes.

15. A gas delivery assembly as recited in claim 7, further comprising a plurality of plugs, wherein said plugs separate a plurality of honeycomb panels of said honeycomb core assembly, said plugs are configured and arranged to provide support for honeycomb panels in said plurality of honeycomb panels which are not rigid enough to support themselves.

16. A gas delivery assembly as recited in claim 1,
wherein said baffle honeycomb core comprises a plurality of spaced apart honeycomb panels forming a plurality of volume portions in said plenum chamber, and said gas inlet supplies gas through a plurality of openings in said first plate to each of said plurality of volume portions.

17. A gas delivery assembly as recited in claim 16,
wherein said plurality of honeycomb panels includes a first, a second and a third space apart honeycomb panels forming said plurality of volume portions in said plenum chamber,
said plurality of openings includes a central opening, a first lateral opening and a second lateral opening,
said central opening opens into and supplies gas to a volume in said plenum chamber between said first plate and said first honeycomb panel,
said first lateral opening opens into and supplies gas to a volume in said plenum chamber between said first honeycomb panel and said second honeycomb panel,
said second lateral opening opens into and supplies gas to a volume in said plenum chamber between said second honeycomb panel and said third honeycomb panel.

18. A gas delivery assembly as recited in claim 7,
wherein said at least one honeycomb panel comprises a contoured surface.

19. A gas delivery assembly as recited in claim 18,
wherein said contoured surface is such that said honeycomb panel is thicker in a central portion thereof and thinner in a lateral portion thereof.

20. A gas delivery assembly as recited in claim 19,
wherein said central portion is disposed in the vicinity of said gas inlet which supplies gas through a central opening in said first plate, and a pressure of the gas is higher in a vicinity of said central portion.

21. A gas delivery assembly as recited in claim 20,
wherein a pressure of a gas passing through said central portion is lowered more than the gas passing through said lateral portion.

22. A gas delivery assembly as recited in claim 21,
wherein a distribution of gas pressure after passage through said honeycomb panel is substantially uniform.

23. A gas delivery assembly as recited in claim 18,
wherein said contoured surface is such that said honeycomb panel is thinner in a central portion thereof and thicker in a lateral portion thereof.

24. A gas delivery assembly as recited in claim 23,
wherein said lateral portion is disposed in the vicinity of said gas inlet which supplies gas through a peripheral channel opening in said first plate, and a pressure of the gas is higher in a vicinity of said lateral portion.

25. A gas deliver assembly as recited in claim 24,
wherein a pressure of the gas passing through said lateral portion is lowered more than the gas passing through said central portion.

26. A gas delivery assembly as recited in claim 25,
wherein a distribution of gas pressure after passage through said honeycomb panel is substantially uniform.

27. A gas delivery assembly as recited in claim 1,
wherein said first plate has a contoured surface.

28. A gas delivery assembly as recited in claim 27,
wherein said contoured surface is convex towards said honeycomb core, and said gas inlet supplies gas through a central opening in said central portion of said first plate.

29. A gas delivery assembly as recited in claim 28,
wherein a gas pressure in a vicinity of said central opening is higher than a gas pressure in a vicinity of said peripheral portion.

30. A gas delivery assembly as recited in claim 27,
wherein said contoured surface is concave relative to said honeycomb core, and said gas inlet supplies gas through an annular channel in a periphery of said first plate.

31. A gas delivery assembly as recited in claim 28,
wherein a gas pressure in a vicinity of said peripheral portion is higher than a gas pressure in a vicinity of said central portion.

32. A gas delivery assembly as recited in claim 8,
wherein said at least one honeycomb panel is covered on at least one of its opposing surfaces with a layer, said layer comprising a plurality of holes, and said holes are disposed such that at least a portion of the plurality of holes are aligned with openings in said plurality of cells.

33. A gas delivery assembly as recited in claim 32,
wherein at least a portion of said plurality of cells comprise venting holes arranged to let gas flow laterally between said portion of said plurality of cells.

34. A gas delivery assembly as recited in claim 1,
wherein said second plate includes a gas showerhead injection plate and said plurality of holes are provided on said gas showerhead injection plate.

35. A gas delivery assembly as recited in claim 34,
wherein the holes in said gas showerhead injection plate are arranged to allow gas in said plenum chamber to exit the gas delivery assembly.

36. A gas delivery assembly as recited in claim 1,
wherein said gas delivery assembly is electrically connected to an RF power supply.

37. A gas delivery assembly as recited in claim 36,
wherein at least one of the first plate and the second plate is electrically connected to the RF power supply.

38. A plasma reactor comprising:
a vacuum chamber;
a chuck assembly;
a plasma source assembly; and
a gas delivery assembly including:
a first plate having a gas inlet;
a second plate having a plurality of holes, said second plate being coupled to said first plate and spaced apart from said first plate to form a plenum chamber; and
a baffle honeycomb core disposed between first plate and said second plate inside said plenum chamber.

39. A plasma reactor as recited in claim 38, wherein said plasma source assembly is a capacitively coupled plasma (CCP) source assembly.

40. A plasma reactor as recited in claim 39, wherein said capacitively coupled plasma (CCP) source assembly comprises and electrode assembly constructed and arranged adjacent to the chuck assembly, said electrode assembly and said chuck assembly defining a plasma region there between.

41. A plasma reactor as recited in claim 40,
wherein said electrode assembly includes said first plate and said second plate.

42. A plasma reactor as recited in claim 38, wherein said plasma source assembly is an inductively coupled plasma (ICP) source assembly.

43. A plasma reactor as recited in claim 38, wherein said plasma source assembly is an electrostatically shielded radio frequency (ESRF) plasma source assembly.

44. A plasma reactor as recited in claim 38, wherein the plasma source assembly is an helicon plasma source assembly.

45. A plasma reactor as recited in claim 38, wherein said plasma source assembly is an electron cyclotron resonance (ECR) source assembly.

46. A plasma reactor as recited in claim 38, wherein said gas inlet supplies a gas into said plenum chamber.

47. A plasma reactor as recited in claim 46, wherein said gas includes at least one of hydrogen-bromide, octafluorocyclobutane, fluorocarbon compounds, silane, tungsten-tetrachloride, and titanium-tetrachloride.

48. A gas delivery assembly for a plasma apparatus, comprising:
a first plate having a gas inlet;
a second plate coupled to said first plate to form a plenum chamber therebetween,
wherein said second plate includes a gas injection plate having a plurality of holes, and said gas injection plate has a contoured surface such that a length of each of said plurality of holes varies depending on a location of said holes on said contoured surface.

49. A gas delivery assembly as recited in claim 48,
wherein the holes in said gas injection plate are distributed on said contoured surface to allow a gas in said plenum chamber to exit the gas delivery assembly with a substantially uniform pressure distribution.

50. A gas delivery assembly as recited in claim 48,
wherein at least a portion of said plurality of holes includes any of a circular, elliptical or polygonal cross-section.

51. A gas delivery assembly as recited in claim 48,
wherein a size of each of said plurality of holes is selected depending on a location of said holes on said contoured surface.

52. A gas delivery assembly as recited in claim 48,
wherein said contoured surface is such that said gas injection plate is thicker in a central portion thereof and thinner in a peripheral portion thereof.

53. A gas delivery assembly as recited in claim 52,
wherein said central portion is disposed in a vicinity of said gas inlet which supplies gas through a central opening in said first plate, and a pressure of the gas is higher in a vicinity of said central portion.

54. A gas delivery assembly as recited in claim 53,
wherein a pressure of the gas passing through said central portion is lowered more than a pressure of the gas passing through said lateral portion.

55. A gas delivery assembly as recited in claim 54,
wherein a distribution of gas pressure after passage through said injection plate is substantially uniform.

56. A gas delivery assembly as recited in claim 48,
wherein said contoured surface is such that said injection plate is thinner in a central portion thereof and thicker in a lateral portion thereof.

57. A gas delivery assembly as recited in claim 56,
wherein said lateral portion is disposed in a vicinity of said gas inlet which supplies gas through a peripheral opening in said first plate, and a pressure of the gas is higher in a vicinity of said lateral portion.

58. A gas delivery assembly as recited in claim 57,
wherein a pressure of the gas passing through said lateral portion is lowered more than the gas passing through said central portion.

59. A gas delivery assembly as recited in claim 58,
wherein a distribution of gas pressure after passage through said injection plate is substantially uniform.

60. A gas delivery assembly as recited in claim 48,
wherein said contoured surface is such that said injection plate is thinner in a central and a lateral portions thereof and thicker in a portion located between said central portion and said lateral portion.

61. A gas delivery assembly as recited in claim 60,
wherein said portion located between said central and said lateral portions is disposed in a vicinity of said gas inlet which supplies gas through an opening in said first plate, and a pressure of the gas is higher in a vicinity of said portion located between said central and said lateral portions.

62. A gas delivery assembly as recited in claim 61,
wherein a pressure of the gas passing through said portion located between said central and said lateral portions is lowered more than the gas passing through said central and said lateral portions.

63. A gas delivery assembly as recited in claim 62,
wherein a distribution of gas pressure after passage through said injection plate is substantially uniform.

64. A gas delivery assembly as recited in claim 48,
wherein said contoured surface is such that said injection plate is thicker in a central and a lateral portions thereof and thinner in a portion located between said central portion and said lateral portion.

65. A gas delivery assembly as recited in claim 64,
wherein said central and said lateral portions are disposed in a vicinity of said gas inlet which supplies gas through central and lateral openings in said first plate, and a pressure of the gas is higher in a vicinity of said central and said lateral portions.

66. A gas delivery assembly as recited in claim 65,
wherein a pressure of the gas passing through said central and said lateral portions is lowered more than the gas passing through said portion located between said central and said lateral portions.

67. A gas delivery assembly as recited in claim 66,
wherein a distribution of gas pressure after passage through said injection plate is substantially uniform.

68. A gas delivery assembly as recited in claim 48,
wherein said gas inlet opens into various portions of said plenum chamber.

69. A gas delivery assembly as recited in claim 48,
wherein said gas inlet supplies gas through a plurality of openings in said first plate.

70. A gas delivery assembly as recited in claim 48, further comprising a gas baffle assembly disposed between said first plate and said second plate inside said plenum chamber.

71. A gas delivery assembly as recited in claim 70,
wherein said gas baffle assembly includes at least one baffle plate.

72. A gas delivery assembly as recited in claim 71,
wherein said baffle plate comprises a plurality of holes.

73. A gas delivery assembly as recited in claim 72,
wherein said plurality of holes in said baffle plate have varying sizes and said holes are arranged to control a distribution of gas pressure in said plenum chamber.

74. A gas delivery assembly as recited in claim 70,
wherein said gas baffle assembly includes at least one honeycomb panel.

75. A gas delivery assembly as recited in claim 74,
wherein said honeycomb panel comprises a plurality of cells.

76. A gas delivery assembly as recited in claim 75,
wherein said cells have varying sizes and said cells are arranged to control a distribution of gas pressure in said plenum chamber.

77. A gas delivery assembly as recited in claim 48,
wherein said gas delivery assembly is electrically connected to an RF power supply.

78. A gas delivery assembly as recited in claim 77,
wherein at least one of the first plate and the second plate is electrically connected to the RF power supply.

79. A plasma reactor comprising:
a vacuum chamber;
a chuck assembly disposed in said chamber;
a plasma source assembly disposed to create a plasma in said chamber; and
a gas delivery assembly disposed to introduce gas in said chamber, said gas delivery assembly including:
a first plate having a gas inlet;
a second plate coupled to said first plate to form a plenum chamber there between,
wherein said second plate includes a gas injection plate having a plurality of holes, and said gas injection plate has a contoured surface such that a length of each of said plurality of holes varies depending on location of said holes on said contoured surface.

80. A plasma reactor as recited in claim 79, wherein said plasma source assembly is a capacitively coupled plasma (CCP) source assembly.

81. A plasma reactor as recited in claim 80, wherein said capacitively coupled plasma (CCP) source assembly comprises an electrode assembly constructed and arranged adjacent to the chuck assembly, said electrode assembly and said chuck assembly defining a plasma region therebetween.

82. A plasma reactor as recited in claim 81,
wherein said electrode assembly includes said first plate and said second plate.

83. A plasma reactor as recited in claim 79, wherein said plasma source assembly is an inductively coupled plasma (ICP) source assembly.

84. A plasma reactor as recited in claim 79, wherein said plasma source assembly is an electrostatically shielded radio frequency (ESRF) plasma source assembly.

85. A plasma reactor as recited in claim 79, wherein said plasma source assembly is an helicon plasma source assembly.

86. A plasma reactor as recited in claim 79, wherein said plasma source assembly is an electron cyclotron resonance (ECR) source assembly.

87. A plasma reactor as recited in claim 79, wherein said gas inlet supplies a gas into said plenum chamber.

88. A plasma reactor as recited in claim 87, wherein said gas includes at least one of hydrogen-bromide, octafluorocyclobutane, fluorocarbon compounds, silane, tungsten-tetrachloride, and titanium-tetrachloride.
